(19) United States
(12) Patent Application Publication
(10) Pub. No.: US 2025/0105236 A1
(43) Pub. Date: Mar. 27, 2025

(54) SEMICONDUCTOR PACKAGE

(71) Applicant: SAMSUNG ELECTRONICS CO., LTD., SUWON-SI (KR)

(72) Inventor: Hong Jin KIM, Suwon-si (KR)

(21) Appl. No.: 18/660,294

(22) Filed: May 10, 2024

(30) Foreign Application Priority Data
Sep. 22, 2023 (KR) 10-2023-0127373
Oct. 11, 2023 (KR) 10-2023-0135104

(51) Int. Cl. H01L 25/18; H01L 23/00

(52) U.S. Cl. CPC H01L 25/18; H01L 24/08; H01L 24/16; H01L 24/32; H01L 24/48; H01L 24/73; H01L 2224/08225; H01L 2224/16227; H01L 2224/32145; H01L 2224/32225; H01L 2224/48147; H01L 2224/48225; H01L 2224/73265; H01L 2225/06506; H01L 2225/0651; H01L 2225/06562; H01L 2924/1815

(57) ABSTRACT

A semiconductor package includes a substrate extending in first and second directions crossing each other. A first spacer is on the substrate. A first semiconductor chip stack is on the first spacer and includes semiconductor chips stacked in a third direction. A second spacer is disposed on the substrate and is spaced apart from the first spacer in the first direction. A second semiconductor chip stack is on the second spacer and includes semiconductor chips stacked in the third direction. A mold layer integrally covers the first and second semiconductor chip stacks and directly contacts side surfaces of the first and second spacers. The first and second semiconductor chip stacks are spaced apart from each other in the first direction. A width of the first spacer in the first direction is greater than a width of the second spacer in the first direction.

### CROSS-REFERENCE TO RELATED APPLICATIONS

This application claims priority under 35 U.S.C. § 119 to Korean Patent Application No. 10-2023-0127373, filed on Sep. 22, 2023 in the Korean Intellectual Property Office (KIPO) and Korean Patent Application No. 10-2023-0135104, filed on Oct. 11, 2023 in KIPO, the disclosures of which are incorporated by reference in their entireties herein.

### 1. Technical Field

The present disclosure relates to a semiconductor package.

### 2. Discussion of Related Art

Electronic components have become increasingly miniaturized and lightweight. Along with this recent trend, there has been a demand for the reduction of the size of semiconductor packages to be mounted thereon. While an area of a package is limited, the size and number of semiconductor chips that fit inside the package have increased.

Therefore, research is being conducted for efficiently disposing the semiconductor chips within the limited area of the package.

### SUMMARY

Aspects of embodiments of the present disclosure provide a semiconductor package having an increased degree of integration.

However, aspects of the present disclosure are not restricted to the one set forth herein. The above and other aspects of embodiments of the present disclosure will become more apparent to one of ordinary skill in the art to which the present disclosure pertains by referencing the detailed description of embodiments of the present disclosure given below.

According to an embodiment of the present disclosure, a semiconductor package includes a substrate extending in a first direction and a second direction intersecting the first direction. A first spacer is disposed on the substrate. A first semiconductor chip stack is disposed on the first spacer. The first semiconductor chip stack includes a plurality of semiconductor chips stacked in a third direction intersecting the first direction and the second direction. A second spacer is disposed on the substrate. The second spacer is spaced apart from the first spacer in the first direction. A second semiconductor chip stack is disposed on the second spacer. The second semiconductor chip stack includes a plurality of semiconductor chips stacked in the third direction. A mold layer integrally covers the first semiconductor chip stack and the second semiconductor chip stack. The mold layer is in direct contact with side surfaces of the first spacer and side surfaces of the second spacer. The first semiconductor chip stack and the second semiconductor chip stack are spaced apart from each other in the first direction. A width of the first spacer in the first direction is greater than a width of the second spacer in the first direction.

According to an embodiment of the present disclosure, a semiconductor package includes a substrate extending in a first direction and a second direction intersecting the first direction. A first spacer is disposed on the substrate. A first semiconductor chip stack is disposed on the first spacer. The first semiconductor chip stack includes a plurality of first semiconductor chips stacked in a third direction intersecting the first direction and the second direction. A second spacer is disposed on the substrate. The second spacer is spaced apart from the first spacer in the first direction. A second semiconductor chip stack is disposed on the second spacer. The second semiconductor chip stack includes a plurality of second semiconductor chips stacked in the third direction. A mold layer integrally covers the first semiconductor chip stack and the second semiconductor chip stack. The mold layer is in direct contact with side surfaces of the first spacer and side surfaces of the second spacer. The first semiconductor chip stack and the second semiconductor chip stack do not overlap each other in the third direction. A width of the first spacer in the first direction is greater than a width of the second spacer in the first direction.

According to an embodiment of the present disclosure, a semiconductor package includes a substrate extending in a first direction and a second direction intersecting the first direction. A first spacer is disposed on the substrate. A first semiconductor chip stack is disposed on the first spacer. The first semiconductor chip includes a plurality of first semiconductor chips stacked in a third direction intersecting the first direction and the second direction. A second spacer is disposed on the substrate. The second spacer is spaced apart from the first spacer in the first direction. A second semiconductor chip stack is disposed on the second spacer. The second semiconductor chip includes a plurality of second semiconductor chips stacked in the third direction. A mold layer integrally covers the first semiconductor chip stack and the second semiconductor chip stack. The mold layer is in direct contact with side surfaces of the first spacer and side surfaces of the second spacer. A controller is disposed between the first spacer and the second spacer and disposed on the substrate. The first spacer comprises a first silicon layer, and a first bonding layer disposed between the first silicon layer and the substrate. The second spacer includes a second silicon layer, and a second bonding layer disposed between the second silicon layer and the substrate. A width of the first spacer in the first direction is greater than a width of the second spacer in the first direction.

### BRIEF DESCRIPTION OF DRAWINGS

The above and other aspects and features of the present disclosure will become more apparent by describing in detail non-limiting embodiments thereof with reference to the attached drawings, in which:

FIG. 1 is a plan view for explaining the semiconductor package according to an embodiment of the present disclosure;

FIG. 2 is a cross-sectional view taken along line A-A of FIG. 1 according to an embodiment of the present disclosure;

FIG. 3 is a diagram for explaining a semiconductor package according to an embodiment of the present disclosure;

FIG. 4 is a diagram for explaining a semiconductor package according to an embodiment of the present disclosure;

FIG. 5 is a diagram for explaining a semiconductor package according to an embodiment of the present disclosure;

FIG. 6 is a diagram for explaining a semiconductor package according to an embodiment of the present disclosure;

FIG. 7 is a diagram for explaining a semiconductor package according to an embodiment of the present disclosure;

FIG. 8 is a diagram for explaining a semiconductor package according to an embodiment of the present disclosure;

FIG. 9 is a diagram for explaining a semiconductor package according to an embodiment of the present disclosure;

FIG. 10 is a diagram for explaining semiconductor packages according to an embodiment of the present disclosure;

FIG. 11 is a diagram for explaining a semiconductor package according to an embodiment of the present disclosure.

### DETAILED DESCRIPTION OF EMBODIMENTS

Embodiments of the present disclosure will be described in detail below with reference to the accompanying drawings. The same reference numerals will be used for the same components in the drawings, and repeated description thereof will be omitted for economy of description.

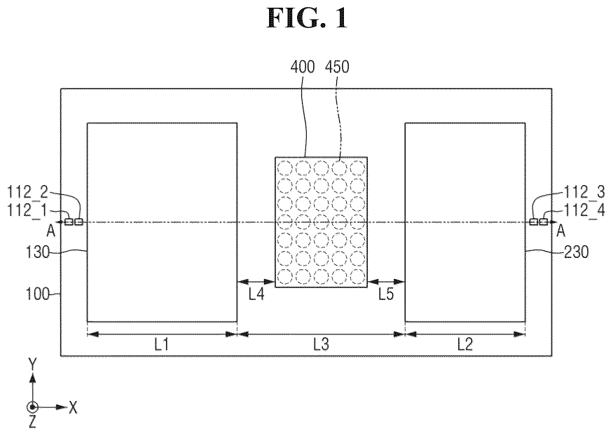

Hereinafter, a semiconductor package according to some embodiments of the present disclosure will be described with reference to FIGS. 1 to 11.

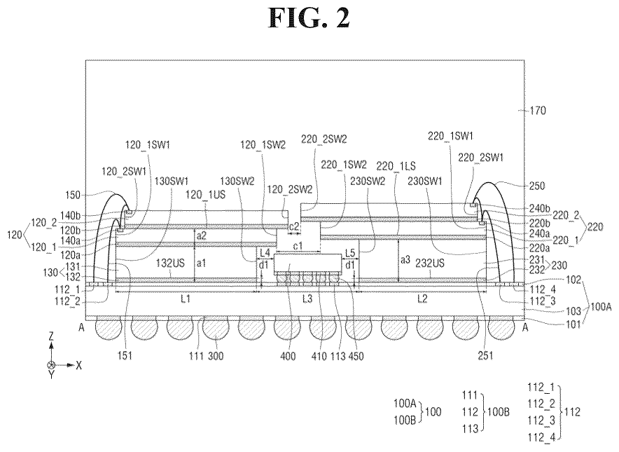

FIG. 1 is a plan view for explaining the semiconductor package according to some embodiments of the present disclosure. FIG. 2 is a cross-sectional view taken along line A-A of FIG. 1.

Referring to FIGS. 1 and 2, the semiconductor package according to some embodiments of the present disclosure may include a substrate 100, a first spacer 130, a second spacer 230, a first semiconductor chip stack 120, a second semiconductor chip stack 220, a mold layer 170, and a controller 400.

In an embodiment, the substrate 100 may be a semiconductor package substrate 100. The substrate 100 may be, for example, a printed circuit board (PCB), a lead frame (LF), a ceramic substrate, a silicon wafer or a wiring board. The printed circuit board may include a rigid printed circuit board (Rigid PCB), a flexible printed circuit board (Flexible PCB) or a rigid flexible printed circuit board (Rigid Flexible PCB). However, embodiments of the present disclosure are not necessarily limited thereto.

The substrate 100 may extend in a first direction X. Further, the substrate 100 may extend in a second direction Y that intersects the first direction X. For example, in an embodiment, the first direction X and the second direction Y may be perpendicular to each other. However, embodiments of the present disclosure are not necessarily limited thereto and the first direction X and the second direction Y may cross each other at various different directions. The first direction X and the second direction Y may each mean a direction parallel to an upper side of the substrate 100.

The third direction Z may intersect the first direction X and the second direction Y. For example, in an embodiment the third direction Z may be a direction perpendicular to the upper side of the substrate 100.

In an embodiment, the substrate 100 may include an insulating structure 100A and a wiring structure 100B.

The insulating structure 100A may include a first passivation layer 101, a second passivation layer 102, and an insulating layer 103. The insulating layer 103 may be disposed between the first passivation layer 101 and the second passivation layer 102 (e.g., in the third direction Z). The first passivation layer 101 may be disposed on (e.g., disposed directly thereon) a lower side of the insulating layer 103. The second passivation layer 102 may be disposed on (e.g., disposed directly thereon) an upper side of the insulating layer 103.

In an embodiment, the first passivation layer 101 and the second passivation layer 102 may include organic materials such as photosensitive polymer. The photosensitive polymer may include, for example, at least one of photosensitive polyimide, polybenzoxazole, phenolic polymer, and benzocyclobutene-based polymer. The first passivation layer 101 and the second passivation layer 102 may include, for example, but is not necessarily limited to, a photo-imageable dielectric material.

The wiring structure 100B may be disposed inside the insulating structure 100A. In an embodiment, the wiring structure 100B may include a lower wiring pad 111, an upper wiring pad 112, and a connecting pad 113. In an embodiment, a plurality of wiring pad vias which electrically connect the lower wiring pad 111 and the upper wiring pad 112 or electrically connect the lower wiring pad 111 and the connecting pad 113 may be formed in the insulating layer 103.

In an embodiment, the upper wiring pads 112 may include a first upper pad 112_1, a second upper pad 112_2, a third upper pad 112_3, and a fourth upper pad 112_4 inside the second passivation layer 102.

The lower wiring pad 111 may be disposed below the insulating layer 103. The lower wiring pad 111 may be disposed inside the first passivation layer 101.

The lower wiring pad 111 may be electrically connected to the external connecting terminal 300. The lower wiring pad 111 may electrically connect the external connecting terminal 300 and the substrate 100 to each other.

The upper wiring pad 112 may be disposed on the top of the insulating layer 103. The upper wiring pad 112 may be disposed inside the second passivation layer 102.

The first upper pad 112_1 may electrically connect the first semiconductor chip stack 120 and the substrate 100. In an embodiment, the first upper pad 112_1 may be connected to (e.g., electrically connected thereto) a first_2 chip pad 140b of a first_2 semiconductor chip 120_2 through a first connecting part 150. For example, in an embodiment the first connecting part 150 may be a bonding wire.

The second upper pad 112_2 may electrically connect the first semiconductor chip stack 120 and the substrate 100 to each other. In an embodiment, the second upper pad 112_2 may be connected to (e.g., electrically connected thereto) a first_1 chip pad 140a of a first_1 semiconductor chip 120_1 through a third connecting part 151. For example, in an embodiment the third connecting part 151 may be a bonding wire.

The third upper pad 112_3 may electrically connect the second semiconductor chip stack 220 and the substrate 100 to each other. In an embodiment, the third upper pad 112_3 may be connected to (e.g., electrically connected thereto) a second_1 chip pad 240a of a second_1 semiconductor chip 220_1 through a fourth connecting part 251. For example, in an embodiment the fourth connecting part 251 may be a bonding wire.

The fourth upper pad 112_4 may electrically connect the second semiconductor chip stack 220 and the substrate 100 to each other. In an embodiment, the fourth upper pad 112_4 may be connected to (e.g., electrically connected thereto) a second_2 chip pad 240b of a second_2 semiconductor chip 220_2 through a second connecting part 250. For example, in an embodiment the second connecting part 250 may be a bonding wire.

The connecting pad 113 may be disposed on (e.g., disposed directly thereon) the top of the insulating layer 103. The connecting pad 113 may be disposed inside the second passivation layer 102.

The connecting pad 113 may electrically connect a controller 400 and a substrate 100 to each other, which will be described below. In an embodiment, the connecting pad 113 may be connected to the controller chip pad 410 of the controller 400 through the connecting bump 450.

Although the lower wiring pads 111, the first upper pads 112_1, the second upper pads 112_2, the third upper pads 112_3, the fourth upper pads 112_4, and the connecting pads 113 are shown as being formed by the specific number, embodiments of the present disclosure are not necessarily limited thereto. For example, the lower wiring pads 111, the first upper pads 112_1, the second upper pads 112_2, the third upper pads 112_3, the fourth upper pads 112_4, and the connecting pads 113 may be formed by the different number from that shown in some embodiments.

The lower wiring pad 111, the first upper pad 112_1, the second upper pad 112_2, the third upper pad 112_3, the fourth upper pad 112_4, and the connecting pad 113 may include a conductive material. In an embodiment, the lower wiring pad 111, the first upper pad 112_1, the second upper pad 112_2, the third upper pad 112_3, the fourth upper pad 112_4, and the connecting pad 113 may include, for example, gold (Au), silver (Ag), copper (Cu), nickel (Ni) or aluminum (Al).

The first spacer 130 may be disposed on the substrate 100.

In an embodiment, the first spacer 130 may include a first silicon layer 131 and a first bonding layer 132. The first bonding layer 132 may be disposed on the upper side of the substrate 100. The first silicon layer 131 may be disposed on an upper side 132US of the first bonding layer 132. For example, the first bonding layer 132 may be disposed between the first silicon layer 131 and the substrate 100 (e.g., in the third direction Z).

The first silicon layer 131 may include silicon (Si).

The first bonding layer 132 may include a material that chemically bonds the substrate 100 and the first silicon layer 131.

For example, in an embodiment the first bonding layer 132 may be a DAF (Direct Adhesive Film).

As another example, the first bonding layer 132 may include an insulating polymer.

As yet another example, the first bonding layer 132 may include an epoxy-based resins and fillers. The fillers may use at least one or more types selected from a group consisting of silica (SiO₂), alumina (Al₂O₃), silicon carbide (SiC), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and calcium zirconate (CaZrO₃). On the other hand, the materials of the fillers are not necessarily limited thereto, and the fillers may include a metal material and/or an organic material.

The second spacer 230 may be disposed on the substrate 100.

In an embodiment, the second spacer 230 may include a second silicon layer 231 and a second bonding layer 232. The second bonding layer 232 may be disposed on the upper side of the substrate 100. The second silicon layer 231 may be disposed on the upper side 232US of the second bonding layer 232. For example, the second bonding layer 232 may be disposed between the second silicon layer 231 and the substrate 100 (e.g., in the third direction Z).

The second silicon layer 231 may include silicon (Si).

The second bonding layer 232 may include a material that chemically bonds the substrate 100 and the second silicon layer 231.

For example, in an embodiment the second bonding layer 232 may be a DAF (Direct Adhesive Film).

As another example, the second bonding layer 232 may include an insulating polymer.

As yet another example, second bonding layer 232 may include an epoxy-based resins and a filler.

The first spacer 130 and the second spacer 230 may be spaced apart from each other in the first direction X.

A distance in the first direction X between the first spacer 130 and the second spacer 230 may be L3. For example, a distance in the first direction X between an inner wall 130SW2 of the first spacer 130 and an inner wall 230SW2 of the second spacer 230 may be L3.

In some embodiments, L3 may be about 2500 μm. However, embodiments of the present disclosure are not necessarily limited thereto.

The first semiconductor chip stack 120 may be disposed on the first spacer 130. The first semiconductor chip stack 120 may be spaced apart from the substrate 100 in the third direction Z. The first spacer 130 may be disposed between the first semiconductor chip stack 120 and the substrate 100 (e.g., in the third direction Z).

In an embodiment, the first semiconductor chip stack 120 may include a plurality of semiconductor chips 120_1 and 120_2. For example, the first semiconductor chip stack 120 may have a form in which a plurality of semiconductor chips 120_1 and 120_2 are stacked in the third direction Z. While an embodiment shown in FIG. 2 shows the number of the plurality of semiconductor chips as two, embodiments of the present disclosure are not necessarily limited thereto and the number of the plurality of semiconductor chips may vary.

In an embodiment, the semiconductor chips 120_1 and 120_2 may include memory semiconductor chips. Each of the semiconductor chips 120_1 and 120_2 may be, for example, a volatile memory, such as a dynamic random access memory (DRAM) or a static random access memory (SRAM). Alternatively, the semiconductor chips 120_1 and 120_2 may be a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

Each of the adhesive layers 120a and 120b may include, for example, but is not necessarily limited to, a non-conductive film (NCF), a non-conductive paste (NCP), an insulating polymer or an epoxy resin.

The adhesive layers 120a and 120b may attach each adhesive layer to an adjacent layer.

A first_1 adhesive layer 120a may attach the first spacer 130 and the first_1 semiconductor chip 120_1 to each other. For example, the first_1 adhesive layer 120a may attach the first silicon layer 131 and the first_1 semiconductor chip 120_1 to each other.

The first_1 adhesive layer 120a may be disposed between the first silicon layer 131 and the first_1 semiconductor chip 120_1 (e.g., in the third direction Z).

A first_2 adhesive layer 120b may attach the first_1 semiconductor chip 120_1 and the first_2 semiconductor chip 120_2 to each other.

The first_2 adhesive layer 120b may be disposed between the first_1 semiconductor chip 120_1 and the first_2 semiconductor chip 120_2 (e.g., in the third direction Z).

In an embodiment, the first semiconductor chip stack 120 may have a stepped form. For example, the first_1 semiconductor chip 120_1 and the first_2 semiconductor chip 120_2 may not completely overlap in the third direction Z and may be partially offset from each other.

In some embodiments, the widths of each semiconductor chip in the first direction X may be equal to each other. For example, the width of the first_1 semiconductor chip 120_1 in the first direction X may be equal to the width of the first_2 semiconductor chip 120_2 in the first direction X.

In some embodiments, the thicknesses of each semiconductor chip in the third direction Z may be equal to each other. For example, the thickness of the first_1 semiconductor chip 120_1 in the third direction Z may be equal to the thickness of the first_2 semiconductor chip 120_2 in the third direction Z.

In some embodiments, the width of the first_1 adhesive layer 120a in the first direction X may be equal to the width of the first_1 semiconductor chip 120_1 in the first direction X.

In some embodiments, the width of the first_2 adhesive layer 120b in the first direction X may be equal to the width of the first_2 semiconductor chip 120_2 in the first direction X.

In some embodiments, an inner wall 120_2SW2 of the first_2 semiconductor chip 120_2 may be present on the inner side of an inner wall 120_1SW2 of the first_1 semiconductor chip 120_1. For example, the inner wall 120_2SW2 of the first_2 semiconductor chip 120_2 may be disposed on (e.g., disposed directly thereon) the inner side of the inner wall 120_1SW2 of the first_1 semiconductor chip 120_1.

In this specification, the term “inner side” refers to a direction close to the center of the substrate 100. In contrast, the outer side may be a direction opposite to the inner side in the first direction X. For example, the controller 400 may be disposed on the inner side of the first spacer 130. Furthermore, the controller 400 may be disposed on the inner side of the second spacer 230. In contrast, the first upper pad 112_1 and the second upper pad 112_2 may be disposed on the outer side of the first spacer 130. Furthermore, a third upper pad 112_3 and a fourth upper pad 112_4 may be disposed on the outer side of the second spacer 230.

In some embodiments, an outer wall 120_1SW1 of the first_1 semiconductor chip 120_1 may be located on the outer side of an outer wall 120_2SW1 of the first_2 semiconductor chip 120_2. For example, the outer wall 120_1SW1 of the first_1 semiconductor chip 120_1 may be disposed on the outer side of the outer wall 120_2SW1 of the first_2 semiconductor chip 120_2.

In some embodiments, the outer wall 130SW1 of the first spacer 130 may be aligned (e.g., in the third direction Z) with the outer wall 120_1SW1 of the first_1 semiconductor chip 120_1.

In some embodiments, the inner wall 130SW2 of the first spacer 130 may not be aligned (e.g., in the third direction Z) with the inner wall 120_1SW2 of the first_1 semiconductor chip 120_1.

The first_1 chip pad 140a may be disposed on the top of the first_1 semiconductor chip 120_1. The first_2 chip pad 140b may be disposed on the top of the first_2 semiconductor chip 120_2.

The first_1 chip pad 140a may be connected to (e.g., electrically connected thereto) the second upper pad 112_2 and the first_2 chip pad 140b at the same time.

The first_1 chip pad 140a may be connected to (e.g., electrically connected thereto) the second upper pad 112_2 through the third connecting part 151. In an embodiment, the first_1 chip pad 140a may be connected to (e.g., electrically connected thereto) the second upper pad 112_2 in a wire bonding manner.

The first_2 chip pad 140b may be connected to (e.g., electrically connected thereto) the first_1 chip pad 140a through the third connecting part 151. In an embodiment, the first_2 chip pad 140b may be connected to (e.g., electrically connected thereto) the first_1 chip pad 140a in a wire bonding manner.

The second semiconductor chip stack 220 may be disposed on the second spacer 230. The second semiconductor chip stack 220 may be spaced apart from the substrate 100 in the third direction Z. A second spacer 230 may be disposed between the second semiconductor chip stack 220 and the substrate 100 (e.g., in the third direction Z).

In an embodiment, the second semiconductor chip stack 220 may include a plurality of semiconductor chips 220_1 and 220_2. For example, the second semiconductor chip stack 220 may have a form in which a plurality of semiconductor chips 220_1 and 220_2 are stacked in the third direction Z. However, the number of the plurality of semiconductor chips of the second semiconductor chip stack 220 may vary.

The semiconductor chips 220_1 and 220_2 may include memory semiconductor chips. In an embodiment, each of the semiconductor chips 220_1 and 220_2 may be, for example, a volatile memory, such as a dynamic random access memory (DRAM) or a static random access memory (SRAM). Alternatively, the semiconductor chips 220_1 and 220_2 may be a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

Each of the adhesive layers 220a and 220b may include, for example, but are not necessarily limited to, a non-conductive film (NCF), a non-conductive paste (NCP), an insulating polymer or an epoxy resin.

The adhesive layers 220a and 220b may attach each adhesive layer to an adjacent layer.

A second_1 adhesive layer 220a may attach the second spacer 230 and the second_1 semiconductor chip 220_1. For example, the second_1 adhesive layer 220a may attach the second silicon layer 231 and the second_1 semiconductor chip 220_1 to each other.

The second_1 adhesive layer 220a may be disposed between the second silicon layer 231 and the second_1 semiconductor chip 220_1 (e.g., in the third direction Z).

A second_2 adhesive layer 220b may attach the second_1 semiconductor chip 220_1 and the second_2 semiconductor chip 220_2 to each other.

The second_2 adhesive layer 220b may be disposed between the second_1 semiconductor chip 220_1 and the second_2 semiconductor chip 220_2 (e.g., in the third direction Z).

In an embodiment, the second semiconductor chip stack 220 may have a stepped form. For example, the second_1 semiconductor chip 220_1 and the second_2 semiconductor chip 220_2 may not completely overlap in the third direction Z and may be offset from each other.

In some embodiments, the widths of each semiconductor chip in the first direction X may be equal to each other. For example, the width of the second_1 semiconductor chip 220_1 in the first direction X may be equal to the width of the second_2 semiconductor chip 220_2 in the first direction X.

In some embodiments, the thicknesses of each semiconductor chip in the third direction Z may be equal to each other. For example, the thickness of the second_1 semiconductor chip 220_1 in the third direction Z may be equal to the thickness of the second_2 semiconductor chip 220_2 in the third direction Z.

In some embodiments, the width of the second_1 adhesive layer 220a in the first direction X may be equal to the width of the second_1 semiconductor chip 220_1 in the first direction X.

In some embodiments, the width of the second_2 adhesive layer 220b in the first direction X may be equal to width of the second_2 semiconductor chip 220_2 in the first direction X.

In some embodiments, an inner wall 220_2SW2 of the second_2 semiconductor chip 220_2 may be present on the inner side of the inner wall 220_1SW2 of the second_1 semiconductor chip 220_1. For example, the inner wall 220_2SW2 of the second_2 semiconductor chip 220_2 may be disposed on (e.g., disposed directly thereon) the inner side of the inner wall 220_1SW2 of the second_1 semiconductor chip 220_1.

In some embodiments, an outer wall 220_1SW1 of the second_1 semiconductor chip 220_1 may be present on the outer side of the outer wall 220_2SW1 of the second_2 semiconductor chip 220_2. For example, the outer wall 220_1SW1 of the second_1 semiconductor chip 220_1 may be disposed on (e.g., disposed directly thereon) the outer side of the outer wall 220_2SW1 of the second_2 semiconductor chip 220_2.

In some embodiments, the outer wall 230SW1 of the second spacer 230 may be aligned with the outer wall 220_1SW1 of the second_1 semiconductor chip 220_1 (e.g., in the third direction Z).

In some embodiments, the inner wall 230SW2 of the second spacer 230 may not be aligned with the inner wall 220_1SW2 of the second_1 semiconductor chip 220_1 (e.g., in the third direction Z).

A second_1 chip pad 240a may be disposed on the top of the second_1 semiconductor chip 220_1. The second_1 chip pad 240a may be simultaneously connected to (e.g., electrically connected thereto) the third upper pad 112_3 and the second_2 chip pad 240b.

The second_1 chip pad 240a may be connected to (e.g., electrically connected thereto) the third upper pad 112_3 through the fourth connecting part 251. In an embodiment, the second_1 chip pad 240a may be connected to (e.g., electrically connected thereto) the third upper pad 112_3 in a wire bonding manner.

The second_1 chip pad 240a may be connected to (e.g., electrically connected thereto) the second_2 chip pad 240b through the fourth connecting part 251. In an embodiment, the second_1 chip pad 240a may be connected to (e.g., electrically connected thereto) the second_2 chip pad 240b in a wire bonding manner.

Although the widths of each of the semiconductor chips 120_1, 120_2, 220_1, and 220_2 in the first direction X are shown to be equal to each other, embodiments of the present disclosure are not necessarily limited thereto.

Although the thicknesses of each of the semiconductor chips 120_1, 120_2, 220_1, and 220_2 in the third direction Z are shown to be equal to each other, embodiments of the present disclosure are not necessarily limited thereto.

Although the widths of each of the adhesive layers 120a, 120b, 220a, and 220b in the first direction X are shown to be equal to each other, embodiments of the present disclosure are not necessarily limited thereto.

Although the thicknesses of each of the adhesive layers 120a, 120b, 220a, and 220b in the third direction Z are shown to be equal to each other, embodiments of the present disclosure are not necessarily limited thereto.

The first semiconductor chip stack 120 and the second semiconductor chip stack 220 may be spaced apart from each other in the first direction X.

The first semiconductor chip stack 120 and the second semiconductor chip stack 220 may not overlap each other in the third direction Z. For example, the first_2 semiconductor chip 120_2 and the second_2 semiconductor chip 220_2 may not overlap each other in the third direction Z.

Since the first semiconductor chip stack 120 and the second semiconductor chip stack 220 do not overlap each other in the third direction Z, a mutual interference between the first semiconductor chip stack 120 and the second semiconductor chip stack 220 can be prevented. In addition, it is possible to reduce physical damage to each of the first semiconductor chip stack 120 and the second semiconductor chip stack 220.

The longest distance in the first direction X between inner walls of the first semiconductor chip stack 120 and the second semiconductor chip stack 220 may be c1. For example, the distance in the first direction X between inner walls of the first_1 semiconductor chip 120_1 and the second_1 semiconductor chip 220_1 may be c1. In an embodiment, a distance in the first direction X between the outer wall of the first_1 semiconductor chip 120_1 and the outer wall of the second_1 semiconductor chip 220_1 may be greater than the distance c1 in the first direction X between inner walls of the first_1 semiconductor chip 120_1 and the second_1 semiconductor chip 220_1.

The shortest distance in the first direction X between inner walls of the first semiconductor chip stack 120 and the second semiconductor chip stack 220 may be c2. For example, the distance in the first direction X between the first_2 semiconductor chip 120_2 and the second_2 semiconductor chip 220_2 may be c2.

The mold layer 170 may integrally cover the first semiconductor chip stack 120, the first spacer 130, the second semiconductor chip stack 220, the second spacer 230, and the controller 400. In an embodiment, the mold layer 170 may be in direct contact with the upper side and side walls of the first semiconductor chip stack 120. The mold layer 170 may be in direct contact with the upper side and side walls of the second semiconductor chip stack 220. The mold layer 170 may be in direct contact with the side wall of the first spacer 130. The mold layer 170 may be in direct contact with the side wall of the second spacer 230.

The mold layer 170 may include an insulating material. For example, in an embodiment the mold layer 170 may include a thermosetting resin such as epoxy resin, and a thermoplastic resin such as polyimide. Further, for example, the mold layer 170 may include a molding material such as an EMC (Epoxy Molding Compound).

The controller 400 may be disposed between the first spacer 130 and the second spacer 230 (e.g., in the first direction X). The connecting pad 113 may be electrically connected to the controller 400. The controller 400 may be a logic chip that controls the memory chips. For example, in an embodiment the logic chip, may include, but is not necessarily limited to, an application processor (AP) such as a CPU (Central Processing Unit), a GPU (Graphic Processing Unit), a FPGA (Field-Programmable Gate Array), a digital signal processor, a cryptographic processor, a microprocessor, a microcontroller, and an ASIC (Application-Specific IC).

In an embodiment, the controller 400 may be flip-chip bonded onto the substrate 100. The controller 400 may be electrically connected to the substrate 100 through the connecting bumps 450.

The controller 400 may include a controller chip pad 410. The controller chip pad 410 may be disposed on (e.g., disposed directly thereon) the lower side of the controller 400.

The connecting bumps 450 may be disposed on (e.g., disposed directly thereon) the controller chip pads 410. The connecting bump 450 may be disposed between the controller chip pad 410 of the controller 400 and the connecting pad 113 (e.g., in the third direction Z). The connecting bump 450 may be in direct contact with the bottom of the controller chip pad 410 and the top of the connecting pad 113.

The connecting bumps 450 may electrically connect the controller 400 and the substrate 100 to each other. The controller 400 may receive electrical signals from the substrate 100 through the lower bump.

A plurality of external connecting terminals 300 may be formed under the substrate 100. The external connecting terminals 300 may be disposed to be electrically connected to the substrate 100. The external connecting terminals 300 may be in direct contact with the lower wiring pads 111.

In some embodiments, the external connecting terminals 300 may electrically connect the semiconductor package including the substrate 100 to other semiconductor packages.

In some embodiments, the external connecting terminals 300 may electrically connect a semiconductor package including the substrate 100 to another semiconductor element.

Although FIG. 2 shows that the external connecting terminals 300 are solder balls, embodiments of the present disclosure are not necessarily limited thereto. For example, in some embodiments the external connecting terminals 300 may be solder bumps, grid arrays conductive tabs, or the like.

Referring to FIG. 2 again, the width of the first spacer 130 in the first direction X may be L1. Further, the width of the second spacer 230 in the first direction X may be L2. In an embodiment, L1 may be a value greater than L2.

The thickness of the first spacer 130 in the third direction Z may be a1. The thickness of the second spacer 230 in the third direction Z may be a3. In an embodiment, a3 may be a value greater than a1.

In an embodiment, a1 and a3 may be, but are not necessarily limited to, about 100 μm.

For example, in the first spacer 130 and the second spacer 230, the width in the first direction X and the thickness in the third direction Z may be different from each other. Therefore, the first spacer 130 and the second spacer 230 may not be symmetrical to each other in the first direction X. For example, the first spacer 130 and the second spacer 230 may have an asymmetric structure with respect to each other.

In an embodiment in which the first spacer 130 and the second spacer 230 have an asymmetric structure with respect to each other, the degree of integration of the semiconductor package may be increased compared to an embodiment in which the first spacer 130 and the second spacer 230 have a symmetric structure with respect to each other.

In an embodiment in which the first spacer 130 and the second spacer 230 structure have a symmetrical structure with respect to each other, the sum of the length L1 of the first spacer 130 in the first direction X and the length L1 of the second spacer 230 in the first direction L1 may be 2×L1. On the other hand, in an embodiment in which the first spacer 130 and the second spacer 230 structure have an asymmetric structure with respect to each other, the sum of the length L1 of the first spacer 130 in the first direction X and the length L2 of the second spacer 230 in the first direction X may be L1+L2.

Since the dimension of L2 is less than L1, it is possible to increase the degree of integration in the first direction X in an embodiment having the asymmetric structure compared to that in the case of the symmetric structure.

An upper side 120_1US of the first_1 semiconductor chip 120_1 may not be disposed on the same plane as the upper side of the second spacer 230 (e.g., in the third direction Z).

For example, on the basis of (e.g., with respect to) the upper side of the substrate 100, the upper side 120_1US of the first_1 semiconductor chip 120_1 may be disposed to be higher than the upper side of the second spacer 230 (e.g., in the third direction Z).

For example, on the basis of the upper side of the substrate 100, the upper side of the first_2 adhesive layer 120b may be disposed to be higher than the upper side of the second_1 adhesive layer 220a (e.g., in the third direction Z).

For example, on the basis of the upper side of the substrate 100, the upper side of the first_2 semiconductor chip 120_2 may be disposed to be higher than the upper side of the second_1 semiconductor chip 220_1 (e.g., in the third direction Z).

For example, on the basis of the upper side of the substrate 100, the upper side 120_1US of the first_1 semiconductor chip 120_1 may be disposed to be higher than the lower side 220_1LS of the second_1 semiconductor chip 220_1 (e.g., in the third direction Z).

In an embodiment, the sum of the thickness a1 of the first spacer 130 in the third direction Z and the thickness a2 of the set of the first_1 semiconductor chip 120_1 and the first_1 adhesive layer 120a in the third direction Z may be greater than the thickness 3a of the second spacer 230 in the third direction Z.

In an embodiment, the thickness a2 of the set of the first_1 semiconductor chip 120_1 and the first_1 adhesive layer 120a in the third direction Z may be about 60 μm. However, embodiments of the present disclosure are not necessarily limited thereto.

In an embodiment, the thickness d1 of the first bonding layer 132 in the third direction Z may be equal to the thickness dl of the second bonding layer 232 in the third direction Z.

For example, the height of the upper side 132US of the first bonding layer 132 may be equal to the height of the upper side 232US of the second bonding layer 232 on the basis of the upper side of the substrate 100.

A distance between the controller 400 and the first spacer 130 in the first direction may be L4, and a distance between the controller 400 and the second spacer 230 in the first direction may be L5. For example, in an embodiment L4 and L5 may be about 180 μm. However, embodiments of the present disclosure are not necessarily limited thereto.

Although the dimensions of L4 and L5 are shown in FIG. 2 as being the same as each other, embodiments of the present disclosure are not necessarily limited thereto. For example, in some embodiments the length of L4 may be less than L5.

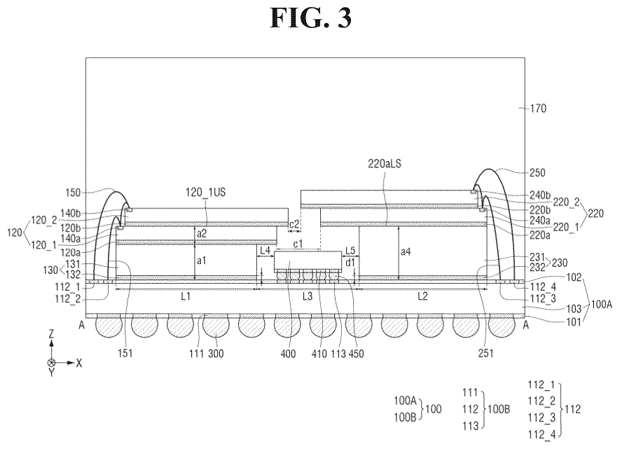

FIG. 3 is a diagram for explaining a semiconductor package according to some embodiments of the present disclosure. For convenience of explanation, the explanation will focus on the points that are different from those explained using FIGS. 1 and 2 and a repeated description of identical or similar elements may be omitted for economy of description.

Referring to FIG. 3, in an embodiment the upper side 120_1US of the first_1 semiconductor chip 120_1 may be disposed on the same plane as the upper side of the second spacer 230 (e.g., in the third direction Z).

In an embodiment, the upper side of the first_2 adhesive layer 120b may be disposed on the same plane as the upper side of the second_1 adhesive layer 220a (e.g., in the third direction Z).

In an embodiment, the upper side of the first_2 semiconductor chip 120_2 may be disposed on the same plane as the upper side of the second_1 semiconductor chip 220_1 (e.g., in the third direction Z).

In an embodiment, the height of the upper side 120_1US of the first_1 semiconductor chip 120_1 may be equal to the height of a lower side 220aLS of the second_1 adhesive layer 220a on the basis of the upper side of the substrate 100.

In an embodiment, the height of the lower side 220aLS of the second_1 adhesive layer 220a may be equal to the height of the upper side of the second spacer 230.

In an embodiment, the sum of the thickness a1 of the first spacer 130 in the third direction Z and the thickness a2 of the set of the first_1 semiconductor chip 120_1 and the first_1 adhesive layer 120a in the third direction Z may be equal to a thickness a4 of the second spacer 230 in the third direction Z.

In an embodiment, the first semiconductor chip stack 120 may include two layers including the first_1 semiconductor chip 120_1 and the first_2 semiconductor chip 120_2. The second semiconductor chip stack 220 may include two layers including the second_1 semiconductor chip 220_1 and the second_2 semiconductor chip 220_2.

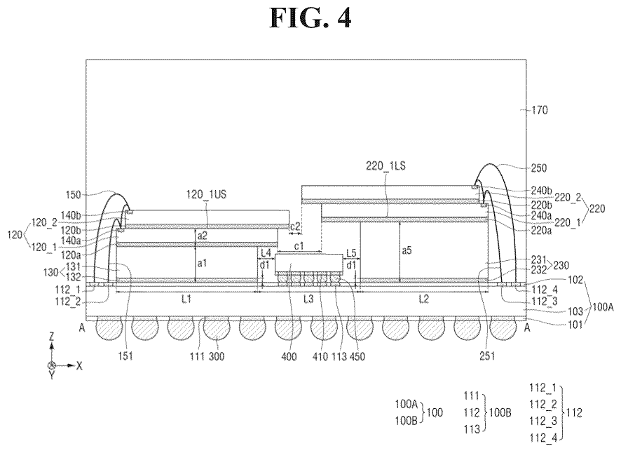

FIG. 4 is a diagram for explaining a semiconductor package according to some embodiments of the present disclosure. For convenience of explanation, the explanation will focus on the points that are different from those explained using FIGS. 1 and 2 and a repeated description of identical or similar elements may be omitted for economy of description.

Referring to FIG. 4, in an embodiment the upper side 120_1US of the first_1 semiconductor chip 120_1 may not be disposed on the same plane as the upper side of the second spacer 230 (e.g., in the third direction Z).

For example, on the basis of the upper side of the substrate 100, the upper side 120_1US of the first_1 semiconductor chip 120_1 may be disposed to be lower than the upper side of the second spacer 230 (e.g., in the third direction Z).

For example, on the basis of the upper side of the substrate 100, the upper side of the first_2 adhesive layer 120b may be disposed to be lower than the upper side of the second_1 adhesive layer 220a (e.g., in the third direction Z).

For example, on the basis of the upper side of the substrate 100, the upper side of the first_2 semiconductor chip 120_2 may be disposed to be lower than the upper side of the second_1 semiconductor chip 220_1 (e.g., in the third direction Z).

For example, on the basis of the upper side of the substrate 100, the upper side 120_1US of the first_1 semiconductor chip 120_1 may be disposed to be lower than the lower side 220_1LS of the second_1 semiconductor chip 220_1 (e.g., in the third direction Z).

In an embodiment, the sum of the thickness a1 of the first spacer 130 in the third direction Z and the thickness a2 of the set of the first_1 semiconductor chip 120_1 and the first_1 adhesive layer 120a in the third direction Z may be less than a thickness a5 of the second spacer 230 in the third direction Z.

In an embodiment, the first semiconductor chip stack 120 may include two layers including the first_1 semiconductor chip 120_1 and the first_2 semiconductor chip 120_2. The second semiconductor chip stack 220 may include two layers including the second_1 semiconductor chip 220_1 and the second_2 semiconductor chip 220_2. However, embodiments of the present disclosure are not necessarily limited thereto.

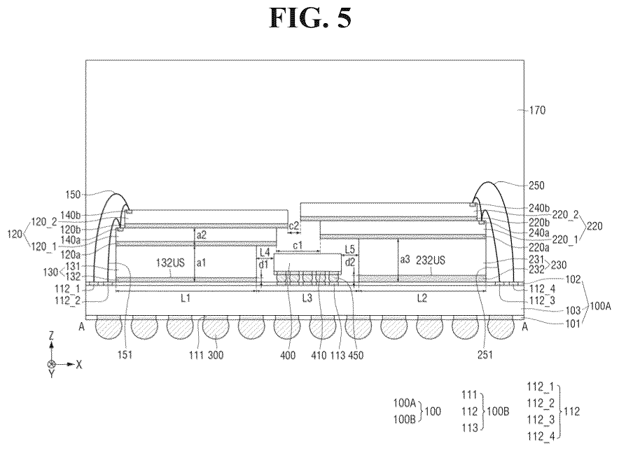

FIG. 5 is a diagram for explaining a semiconductor package according to some embodiments of the present disclosure. For convenience of explanation, the explanation will focus on the points that are different from those explained using FIGS. 1 and 2 and a repeated description of identical or similar elements may be omitted for economy of description.

Referring to FIG. 5, in an embodiment the thickness d1 of the first bonding layer 132 in the third direction Z may not be equal to the thickness d2 of the second bonding layer 232 in the third direction Z. For example, in an embodiment the thickness d2 of the second bonding layer 232 in the third direction Z may be greater than the thickness d1 of the first bonding layer 132 in the third direction Z.

In an embodiment, the height of the upper side 132US of the first bonding layer 132 may be less than the height of the upper side 232US of the second bonding layer 232 on the basis of the upper side of the substrate 100.

In an embodiment, the first semiconductor chip stack 120 may include two layers including the first_1 semiconductor chip 120_1 and the first_2 semiconductor chip 120_2. The second semiconductor chip stack 220 may include two layers including the second_1 semiconductor chip 220_1 and the second_2 semiconductor chip 220_2. However, embodiments of the present disclosure are not necessarily limited thereto.

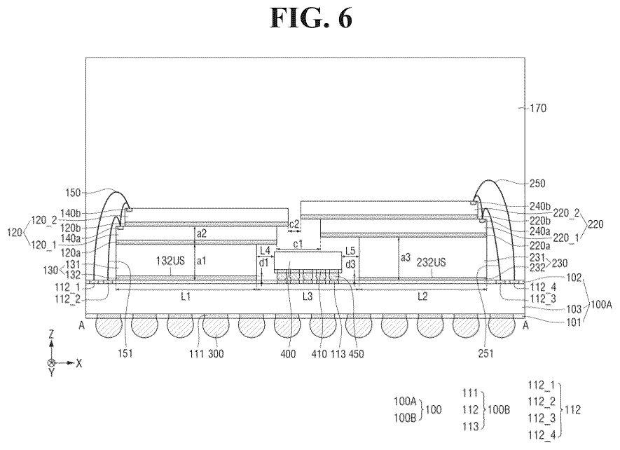

FIG. 6 is a diagram for explaining a semiconductor package according to some embodiments of the present disclosure. For convenience of explanation, the explanation will focus on the points that are different from those explained using FIGS. 1 and 2 and a repeated description of identical or similar elements may be omitted for economy of description.

Referring to FIG. 6, in an embodiment the thickness d1 of the first bonding layer 132 in the third direction Z may not be equal to the thickness d3 of the second bonding layer 232 in the third direction Z. For example, in an embodiment the thickness d3 of the second bonding layer 232 in the third direction Z may be less than the thickness d1 of the first bonding layer 132 in the third direction Z.

In an embodiment, the height of the upper side 132US of the first bonding layer 132 may be greater than the height of the upper side 232US of the second bonding layer 232 on the basis of the upper side of the substrate 100.

In an embodiment, the first semiconductor chip stack 120 may include two layers including the first_1 semiconductor chip 120_1 and the first_2 semiconductor chip 120_2. The second semiconductor chip stack 220 may include two layers including the second_1 semiconductor chip 220_1 and the second_2 semiconductor chip 220_2. However, embodiments of the present disclosure are not necessarily limited thereto.

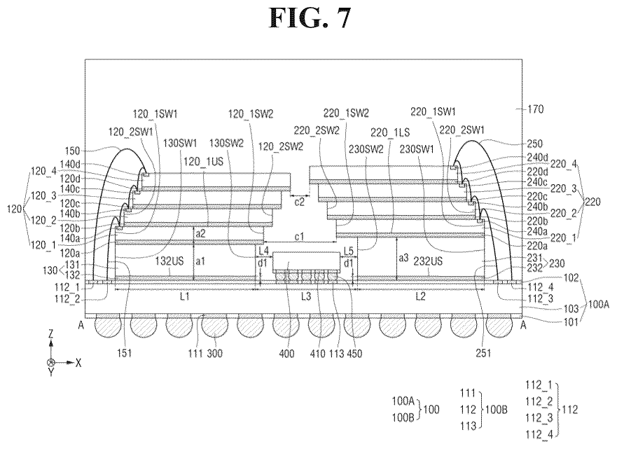

FIG. 7 is a diagram for explaining a semiconductor package according to some embodiments of the present disclosure. For convenience of explanation, the explanation will focus on the points that are different from those explained using FIGS. 1 and 2 and a repeated description of identical or similar elements may be omitted for economy of description.

Referring to FIG. 7, the first semiconductor chip stack 120 may include a plurality of semiconductor chips 120_1, 120_2, 120_3, and 120_4. For example, the first semiconductor chip stack 120 may have a form in which a plurality of semiconductor chips 120_1, 120_2, 120_3, and 120_4 are stacked in the third direction Z.

In an embodiment, the semiconductor chips 120_1, 120_2, 120_3, and 120_4 may include memory chips. In an embodiment, each of the semiconductor chips 120_1, 120_2, 120_3 and 120_4 may be a volatile memory, such as, for example, a dynamic random access memory (DRAM) or a static random access memory (SRAM). Alternatively, the semiconductor chips 120_1, 120_2, 120_3, and 120_4 may be a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

In an embodiment, each of the adhesive layers 120a, 120b, 120c, and 120d may include, for example, but is not necessarily limited to, a non-conductive film (NCF), a non-conductive paste (NCP), an insulating polymer or an epoxy resin.

The adhesive layers 120a, 120b, 120c, and 120d may attach each adhesive layer to an adjacent layer.

A first_1 adhesive layer 120a may attach the first spacer 130 and the first_1 semiconductor chip 120_1 to each other. For example, the first_1 adhesive layer 120a may attach the first silicon layer 131 and the first_1 semiconductor chip 120_1 to each other.

The first_1 adhesive layer 120a may be disposed between the first silicon layer 131 and the first_1 semiconductor chip 120_1 (e.g., in the third direction Z).

A first_2 adhesive layer 120b may attach the first_1 semiconductor chip 120_1 and the first_2 semiconductor chip 120_2 to each other.

The first_2 adhesive layer 120b may be disposed between the first_1 semiconductor chip 120_1 and the first_2 semiconductor chip 120_2 (e.g., in the third direction Z).

A first_3 adhesive layer 120c may attach the first_2 semiconductor chip 120_2 and the first_3 semiconductor chip 120_3 to each other.

The first_3 adhesive layer 120c may be disposed between the first_2 semiconductor chip 120_2 and the first_3 semiconductor chip 120_3 (e.g., in the third direction Z).

A first_4 adhesive layer 120d may attach the first_3 semiconductor chip 120_3 and the first_4 semiconductor chip 120_4 to each other.

The first_4 adhesive layer 120d may be disposed between the first_3 semiconductor chip 120_3 and the first_4 semiconductor chip 120_4 (e.g., in the third direction Z).

In an embodiment, the first semiconductor chip stack 120 may have a stepped form. For example, the first_1 semiconductor chip 120_1 and the first_2 semiconductor chip 120_2 may not completely overlap in the third direction Z and may be offset with each other. Furthermore, the first_2 semiconductor chip 120_2 and the first_3 semiconductor chip 120_3 may not completely overlap in the third direction Z. Further, the first_3 semiconductor chip 120_3 may not completely overlap the first_4 semiconductor chip 120_4 in the third direction Z.

In some embodiments, the widths of each semiconductor chip in the first direction X may be equal to each other. For example, in an embodiment the width of the first_1 semiconductor chip 120_1 in the first direction X, the dimension of the width of the first_2 semiconductor chip 120_2 in the first direction X, the dimension of the width of the first_3 semiconductor chip 120_3 in the first direction X, and the dimension of the width of the first_4 semiconductor chip 120_4 in the first direction X may be equal to each other.

In some embodiments, the thicknesses of each semiconductor chip in the third direction Z may be equal to each other. For example, in an embodiment the thickness of the first_1 semiconductor chip 120_1 in the third direction Z, the thickness of the first_2 semiconductor chip 120_2 in the third direction Z, the thickness of the first_3 semiconductor chip 120_3 in the third direction Z, and the thickness of the first_4 semiconductor chip 120_4 in the third direction Z may be equal to each other.

In an embodiment, the first_1 chip pad 140a may be disposed on the top of the first_1 semiconductor chip 120_1. The first_2 chip pad 140b may be disposed on the top of the first_2 semiconductor chip 120_2. The first_3 chip pad 140c may be disposed on the top of the first_3 semiconductor chip 120_3. The first_4 chip pad 140d may be disposed on the top of the first_4 semiconductor chip 120_4.

In an embodiment, the first_1 chip pad 140a may be connected to (e.g., electrically connected thereto) the second upper pad 112_2 through the third connecting part 151. In an embodiment, the first_1 chip pad 140a may be connected to (e.g., electrically connected thereto) the second upper pad 112_2 in a wire bonding manner.

In an embodiment, the first_2 chip pad 140b may be connected to (e.g., electrically connected thereto) the first_1 chip pad 140a through the third connecting part 151. In an embodiment, the first_2 chip pad 140b may be connected to (e.g., electrically connected thereto) the first_1 chip pad 140a in a wire bonding manner.

In an embodiment, the first_3 chip pad 140c may be connected to (e.g., electrically connected thereto) the first_2 chip pad 140b through the third connecting part 151. In an embodiment, the first_3 chip pad 140c may be connected to (e.g., electrically connected thereto) the first_2 chip pad 140b in a wire bonding manner.

In an embodiment, the first_4 chip pad 140d may be connected to (e.g., electrically connected thereto) the first_3 chip pad 140c through the third connecting part 151. In an embodiment, the first_4 chip pad 140d may be connected to (e.g., electrically connected thereto) the first_3 chip pad 140c in a wire bonding manner.

In an embodiment, the first_4 chip pad 140d may be connected to (e.g., electrically connected thereto) the first upper pad 112_1 through the first connecting part 150. In an embodiment, the first_4 chip pad 140d may be connected to (e.g., electrically connected thereto) the first upper pad 112_1 in a wire bonding manner.

The second semiconductor chip stack 220 may include a plurality of semiconductor chips 220_1, 220_2, 220_3, and 220_4. For example, the second semiconductor chip stack 220 may have a form in which a plurality of semiconductor chips 220_1, 220_2, 220_3, and 220_4 are stacked in the third direction Z. However, embodiments of the present disclosure are not necessarily limited thereto and the number of the plurality of semiconductor chips may vary.

The semiconductor chips 220_1, 220_2, 220_3, and 220_4 may include memory semiconductor chips. In an embodiment, each of the semiconductor chips 220_1, 220_2, 220_3 and 220_4 may be a volatile memory, such as, for example, a dynamic random access memory (DRAM) or a static random access memory (SRAM). Alternatively, the semiconductor chips 220_1, 220_2, 220_3, and 220_4 may be a non-volatile memory such as a flash memory, a PRAM (Phase-change Random Access Memory), a MRAM (Magnetic Random Access Memory), a FeRAM (Ferroelectric Random Access Memory) or a RRAM (Resistive Random Access Memory).

In an embodiment, each of the adhesive layers 220a, 220b, 220c and 220d may include, for example, but is not necessarily limited to, a non-conductive film (NCF), a non-conductive paste (NCP), an insulating polymer or an epoxy resin.

The adhesive layers 220a, 220b, 220c, and 220d may attach each adhesive layer to an adjacent layer.

The second_1 adhesive layer 220a may attach the second spacer 230 and the second_1 semiconductor chip 220_1 to each other. For example, the second_1 adhesive layer 220a may attach the second silicon layer 231 and the second_1 semiconductor chip 220_1 to each other.

The second_1 adhesive layer 220a may be disposed between the second silicon layer 231 and the second_1 semiconductor chip 220_1 (e.g., in the third direction Z).

The second_2 adhesive layer 220b may attach the second_1 semiconductor chip 220_1 and the second_2 semiconductor chip 220_2 to each other.

The second_2 adhesive layer 220b may be disposed between the second_1 semiconductor chip 220_1 and the second_2 semiconductor chip 220_2 (e.g., in the third direction Z).

The second_3 adhesive layer 220c may attach the second_2 semiconductor chip 220_2 and the second_3 semiconductor chip 220_3 to each other.

The second_3 adhesive layer 220c may be disposed between the second_2 semiconductor chip 220_2 and the second_3 semiconductor chip 220_3 (e.g., in the third direction Z).

The second_4 adhesive layer 220d may attach the second_3 semiconductor chip 220_3 and the second_4 semiconductor chip 220_4 to each other.

The second_4 adhesive layer 220d may be disposed between the second_3 semiconductor chip 220_3 and the second_4 semiconductor chip 220_4 (e.g., in the third direction Z).

In an embodiment, the second semiconductor chip stack 220 may have a stepped form. For example, the second_1 semiconductor chip 220_1 and the second_2 semiconductor chip 220_2 may not completely overlap in the third direction Z and may be offset from each other. Furthermore, the second_2 semiconductor chip 220_2 and the second_3 semiconductor chip 220_3 may not completely overlap in the third direction Z and may be offset from each other. The second_3 semiconductor chip 220_3 and the second_4 semiconductor chip 220_4 may not completely overlap in the third direction Z and may be offset from each other.

In some embodiments, the widths of each semiconductor chip in the first direction X may be equal to each other. For example, in an embodiment the width of the second_1 semiconductor chip 220_1 in the first direction X, the width of the second_2 semiconductor chip 220_2 in the first direction X, the width of the second_3 semiconductor chip 220_3 in the first direction X, and the width of the second_4 semiconductor chip 220_4 in the first direction X may be equal to each other.

In some embodiments, the thicknesses of each semiconductor chip in the third direction Z may be equal to each other. For example, in an embodiment the thickness of the second_1 semiconductor chip 220_1 in the third direction Z, the thickness of the second_2 semiconductor chip 220_2 in the third direction Z, the thickness of the second_3 semiconductor chip 220_3 in the third direction Z, and the thickness of the second_4 semiconductor chip 220_4 in the third direction Z may be equal to each other.

A second_1 chip pad 240a may be disposed on the top of the second_1 semiconductor chip 220_1. A second_2 chip pad 240b may be disposed on the top of the second_2 semiconductor chip 220_2. A second_3 chip pad 240c may be disposed on the top of the second_3 semiconductor chip 220_3. A second_4 chip pad 240d may be disposed on the top of the second_4 semiconductor chip 220_4.

The second_1 chip pad 240a may be connected to (e.g., electrically connected thereto) the third upper pad 112_3 through the fourth connecting part 251. In an embodiment, the second_1 chip pad 240a may be connected to (e.g., electrically connected thereto) the third upper pad 112_3 in a wire bonding manner.

The second_2 chip pad 240b may be connected to (e.g., electrically connected thereto) the second_1 chip pad 240a through the fourth connecting part 251. In an embodiment, the second_2 chip pad 240b may be connected to (e.g., electrically connected thereto) the second_1 chip pad in a wire bonding manner.

The second_3 chip pad 240c may be connected to (e.g., electrically connected thereto) the second_2 chip pad 240b through the fourth connecting part 251. In an embodiment, the second_3 chip pad 240c may be connected to (e.g., electrically connected thereto) the second_2 chip pad 240b in a wire bonding manner.

The second_4 chip pad 240d may be connected to (e.g., electrically connected thereto) the second_3 chip pad 240c through the fourth connecting part 251. In an embodiment, the second_4 chip pad 240d may be connected to (e.g., electrically connected thereto) the second_3 chip pad 240c in a wire bonding manner.

The second_4 chip pad 240d may be connected to (e.g., electrically connected thereto) the fourth upper pad 112_4 through the second connecting part 250. In an embodiment, the second_4 chip pad 240d may be connected to (e.g., electrically connected thereto) the fourth upper pad 112_4 in a wire bonding manner.

In an embodiment, the first semiconductor chip stack 120 and the second semiconductor chip stack 220 may not overlap in the third direction Z. For example, the first_4 semiconductor chip 120_4 and the second_4 semiconductor chip 220_4 may not overlap each other in the third direction Z and may be offset from each other.

The longest distance in the first direction X between inner walls of the first semiconductor chip stack 120 and the second semiconductor chip stack 220 may be c1. For example, the distance in the first direction X between the first_1 semiconductor chip 120_1 and the second_1 semiconductor chip 220_1 may be c1.

The shortest distance in the first direction X between the first semiconductor chip stack 120 and the second semiconductor chip stack 220 may be c2. For example, the distance in the first direction X between the first_4 semiconductor chip 120_4 and the second_4 semiconductor chip 220_4 may be c2.

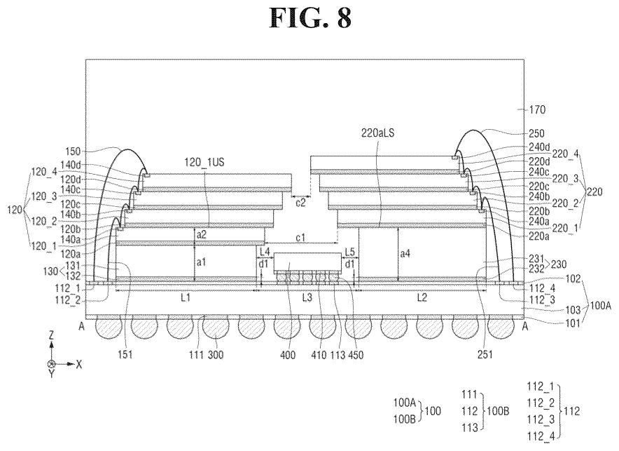

FIG. 8 is a diagram for explaining a semiconductor package according to some embodiments of the present disclosure. For convenience of explanation, the explanation will focus on the points that are different from those explained using FIGS. 1, 2, and 7 and a repeated description of identical or similar elements may be omitted for economy of description.

Referring to FIG. 8, in an embodiment the upper side 120_1US of the first_1 semiconductor chip 120_1 may be disposed on the same plane as the upper side of the second spacer 230 (e.g., in the third direction Z).

In an embodiment, the upper side of the first_2 adhesive layer 120b may be disposed on the same plane as the upper side of the second_1 adhesive layer 220a (e.g., in the third direction Z).

In an embodiment, the upper side of the first_2 semiconductor chip 120_2 may be disposed on the same plane as the upper side of the second_1 semiconductor chip 220_1 (e.g., in the third direction Z).

In an embodiment, the upper side of the first_3 adhesive layer 120c may be disposed on the same plane as the upper side of the second_2 adhesive layer 220b (e.g., in the third direction Z).

In an embodiment, the upper side of the first_3 semiconductor chip 120_3 may be disposed on the same plane as the upper side of the second_2 semiconductor chip 220_2 (e.g., in the third direction Z).

In an embodiment, the upper side of the first_4 adhesive layer 120d may be disposed on the same plane as the upper side of the second_3 adhesive layer 220c (e.g., in the third direction Z).

In an embodiment, the upper side of the first_4 semiconductor chip 120_4 may be disposed on the same plane as the upper side of the second_3 semiconductor chip 220_3 (e.g., in the third direction Z).

In an embodiment, the sum of the thickness a1 of the first spacer 130 in the third direction Z and the thickness a2 of the set of the first_1 semiconductor chip 120_1 and the first_1 adhesive layer 120a in the third direction Z may be equal to the thickness a4 of the second spacer 230 in the third direction Z.

In an embodiment, the first semiconductor chip stack 120 may include four layers including the first_1 semiconductor chip 120_1, the first_2 semiconductor chip 120_2, the first_3 semiconductor chip 120_3, and the first_4 semiconductor chip 120_4. The second semiconductor chip stack 220 may include four layers including the second_1 semiconductor chip 220_1, the second_2 semiconductor chip 220_2, the second_3 semiconductor chip 220_3, and the second_4 semiconductor chip 220_4. However, embodiments of the present disclosure are not necessarily limited thereto and the number of layers of the first and second semiconductor chip stacks 120, 220 may vary.

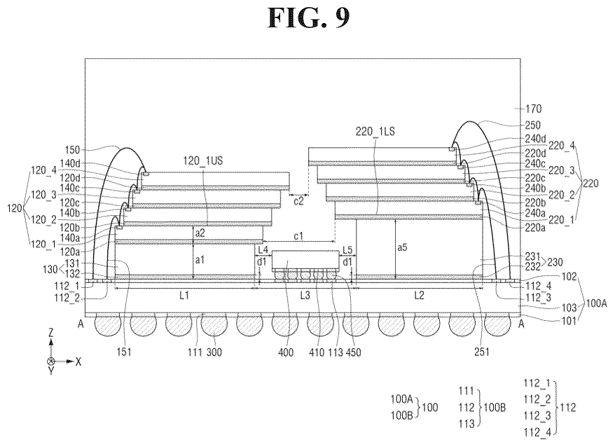

FIG. 9 is a diagram for explaining a semiconductor package according to some embodiments of the present disclosure. For convenience of explanation, the explanation will focus on the points that are different from those explained using FIGS. 1, 2, and 7 and a repeated description of identical or similar elements may be omitted for economy of description.

Referring to FIG. 9, in an embodiment the upper side 120_1US of the first_1 semiconductor chip 120_1 may not be disposed on the same plane as the upper side of the second spacer 230 (e.g., in the third direction Z).

For example, in an embodiment on the basis of the upper side of the substrate 100, the upper side 120_1US of the first_1 semiconductor chip 120_1 may be disposed to be lower than the upper side of the second spacer 230 (e.g., in the third direction Z).

For example, on the basis of the upper side of the substrate 100, the upper side of the first_2 adhesive layer 120b may be disposed to be lower than the upper side of the second_1 adhesive layer 220a (e.g., in the third direction Z).

For example, on the basis of the upper side of the substrate 100, the upper side of the first_2 semiconductor chip 120_2 may be disposed to be lower than the upper side of the second_1 semiconductor chip 220_1 (e.g., in the third direction Z).

For example, on the basis of the upper side of the substrate 100, the upper side of the first_3 adhesive layer 120c may be disposed to be lower than the upper side of the second_2 adhesive layer 220b (e.g., in the third direction Z).

For example, on the basis of the upper side of the substrate 100, the upper side of the first_3 semiconductor chip 120_3 may be disposed to be lower than the upper side of the second_2 semiconductor chip 220_2 (e.g., in the third direction Z).

For example, on the basis of the upper side of the substrate 100, the upper side of the first_4 adhesive layer 120d may be disposed to be lower than the upper side of the second_3 adhesive layer 220c (e.g., in the third direction Z).

For example, on the basis of the upper side of the substrate 100, the upper side of the first_4 semiconductor chip 120_4 may be disposed to be lower than the upper side of the second_3 semiconductor chip 220_3 (e.g., in the third direction Z).

In an embodiment, the sum of the thickness a1 of the first spacer 130 in the third direction Z and the thickness a2 of the set of the first_1 semiconductor chip 120_1 and the first_1 adhesive layer 120a in the third direction Z may be less than the thickness a5 of the second spacer 230 in the third direction Z.

In an embodiment, the first semiconductor chip stack 120 may include four layers including the first_1 semiconductor chip 120_1, the first_2 semiconductor chip 120_2, the first_3 semiconductor chip 120_3, and the first_4 semiconductor chip 120_4. The second semiconductor chip stack 220 may include four layers including the second_1 semiconductor chip 220_1, the second_2 semiconductor chip 220_2, the second_3 semiconductor chip 220_3, and the second_4 semiconductor chip 220_4. However, embodiments of the present disclosure are not necessarily limited thereto and the number of the layers of the first and second semiconductor chip stacks 120, 220 may vary.

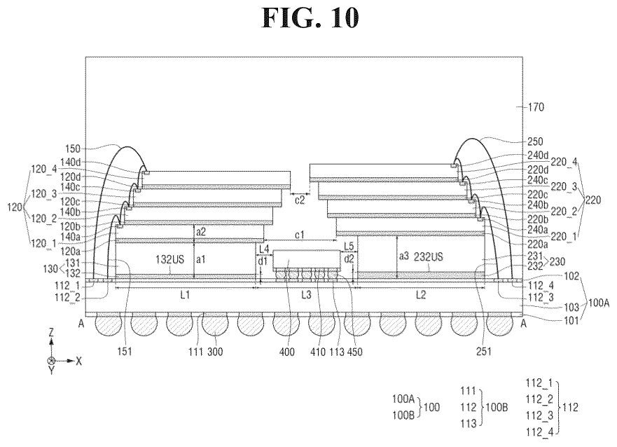

FIG. 10 is a diagram for explaining semiconductor packages according to some embodiments of the present disclosure. For convenience of explanation, the explanation will focus on the points that are different from those explained using FIGS. 1, 2, and 7 and a repeated description of identical or similar elements may be omitted for economy of description.

Referring to FIG. 10, in an embodiment the thickness d1 of the first bonding layer 132 in the third direction Z may not be equal to the thickness d2 of the second bonding layer 232 in the third direction Z. For example, in an embodiment the thickness d2 of the second bonding layer 232 in the third direction Z may be greater than the thickness d1 of the first bonding layer 132 in the third direction Z.

In an embodiment, the first semiconductor chip stack 120 may include four layers including the first_1 semiconductor chip 120_1, the first_2 semiconductor chip 120_2, the first_3 semiconductor chip 120_3, and the first_4 semiconductor chip 120_4. The second semiconductor chip stack 220 may include four layers including the second_1 semiconductor chip 220_1, the second_2 semiconductor chip 220_2, the second_3 semiconductor chip 220_3, and the second_4 semiconductor chip 220_4. However, embodiments of the present disclosure are not necessarily limited thereto and the number of the layers of the first and second semiconductor chip stacks 120, 220 may vary.

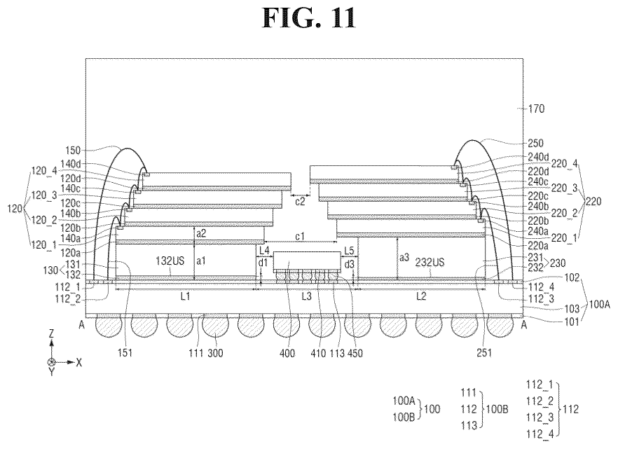

FIG. 11 is a diagram for explaining a semiconductor package according to some embodiments of the present disclosure. For convenience of explanation, the explanation will focus on the points that are different from those explained using FIGS. 1, 2, and 7 and a repeated description of identical or similar elements may be omitted for economy of description.

Referring to FIG. 11, in an embodiment the thickness d1 of the first bonding layer 132 in the third direction Z may not be equal to the thickness d3 of the second bonding layer 232 in the third direction Z. For example, in an embodiment the thickness d3 of the second bonding layer 232 in the third direction Z may be less than the thickness d1 of the first bonding layer 132 in the third direction Z.

In an embodiment, the first semiconductor chip stack 120 may include four layers including the first_1 semiconductor chip 120_1, the first_2 semiconductor chip 120_2, the first_3 semiconductor chip 120_3, and the first_4 semiconductor chip 120_4. The second semiconductor chip stack 220 may include four layers including the second_1 semiconductor chip 220_1, the second_2 semiconductor chip 220_2, the second_3 semiconductor chip 220_3, and the second_4 semiconductor chip 220_4. However, embodiments of the present disclosure are not necessarily limited thereto and the number of the layers of the first and second semiconductor chip stacks 120, 220 may vary.

Although FIGS. 2 to 6 show that the first semiconductor chip stack 120 and the second semiconductor chip stack 220 each include two semiconductor chips, and FIGS. 7 to 11 show that the first semiconductor chip stack 120 and the second semiconductor chip stacks 220 each include four semiconductor chips, the number of semiconductor chips included in each of the semiconductor chip stacks 120 and 220 is not necessarily limited to two or four. For example, the number of semiconductor chips included in each of semiconductor chip stacks 120 and 220 may be three or five or more.

In concluding the detailed description, those skilled in the art will appreciate that many variations and modifications may be made to the described embodiments without substantially departing from the principles of embodiments of the present disclosure. Therefore, the described embodiments of the present disclosure are used in a generic and descriptive sense only and not for purposes of limitation.

What is claimed is:

1. A semiconductor package comprising:
a substrate extending in a first direction and a second direction intersecting the first direction;
a first spacer disposed on the substrate;
a first semiconductor chip stack disposed on the first spacer, the first semiconductor chip stack includes a plurality of semiconductor chips stacked in a third direction intersecting the first direction and the second direction;
a second spacer disposed on the substrate, the second spacer is spaced apart from the first spacer in the first direction;
a second semiconductor chip stack disposed on the second spacer, the second semiconductor chip stack includes a plurality of semiconductor chips stacked in the third direction; and
a mold layer integrally covering the first semiconductor chip stack and the second semiconductor chip stack, the mold layer is in direct contact with side surfaces of the first spacer and side surfaces of the second spacer,
wherein the first semiconductor chip stack and the second semiconductor chip stack are spaced apart from each other in the first direction, and
a width of the first spacer in the first direction is greater than a width of the second spacer in the first direction.

2. The semiconductor package of claim 1, wherein:
a thickness of the first spacer in the third direction is less than a thickness of the second spacer in the third direction.

3. The semiconductor package of claim 1, wherein:
the first semiconductor chip stack comprises a first semiconductor chip disposed on an upper side of the first spacer;
the second semiconductor chip stack comprises a second semiconductor chip disposed on an upper side of the second spacer; and
a thickness of the first semiconductor chip in the third direction is equal to a thickness of the second semiconductor chip in the third direction.

4. The semiconductor package of claim 3, further comprising:
a first adhesive layer between the first semiconductor chip and the first spacer; and
a second adhesive layer between the second semiconductor chip and the second spacer.

5. The semiconductor package of claim 3, wherein:
a height of an upper side of the first semiconductor chip is greater than a height of a lower side of the second semiconductor chip with respect to the upper side of the substrate.

6. The semiconductor package of claim 3, wherein:
a height of an upper side of the first semiconductor chip is the same as a height of the upper side of the second spacer with respect to an upper side of the substrate.

7. The semiconductor package of claim 3, wherein:
a height of an upper side of the first semiconductor chip is less than a height of a lower side of the second semiconductor chip with respect to an upper side of the substrate.

8. The semiconductor package of claim 1, further comprising:
a controller disposed between the first spacer and the second spacer and disposed on the substrate,
wherein the substrate comprises a wiring structure including a first passivation layer and a second passivation layer spaced apart from each other in the third direction, a first wiring layer in the first passivation layer, and a second wiring layer in the second passivation layer,
the first wiring layer comprises a first upper pad and a second upper pad electrically connected to the first semiconductor chip stack through a first bonding wire, a third upper pad and a fourth upper pad electrically connected to the second semiconductor chip stack through a second bonding wire, and a connecting pad electrically connected to the controller, and
the controller is electrically connected to the substrate through a solder ball connected to the connecting pad.

9. A semiconductor package comprising:
a substrate extending in a first direction and a second direction intersecting the first direction;
a first spacer disposed on the substrate;
a first semiconductor chip stack disposed on the first spacer, the first semiconductor chip stack includes a plurality of first semiconductor chips stacked in a third direction intersecting the first direction and the second direction;
a second spacer disposed on the substrate, the second spacer is spaced apart from the first spacer in the first direction;
a second semiconductor chip stack disposed on the second spacer, the second semiconductor chip stack includes a plurality of second semiconductor chips stacked in the third direction; and
a mold layer integrally covering the first semiconductor chip stack and the second semiconductor chip stack, the mold layer is in direct contact with side surfaces of the first spacer and side surfaces of the second spacer,
wherein the first semiconductor chip stack and the second semiconductor chip stack do not overlap each other in the third direction, and
a width of the first spacer in the first direction is greater than a width of the second spacer in the first direction.

10. The semiconductor package of claim 9, wherein:
the first semiconductor chip stack comprises a first semiconductor chip disposed on an upper side of the first spacer, and a second semiconductor chip disposed on the first semiconductor chip;
the second semiconductor chip stack comprises a third semiconductor chip disposed on an upper side of the second spacer, and a fourth semiconductor chip disposed on the third semiconductor chip; and
thicknesses of the first semiconductor chip, the second semiconductor chip, the third semiconductor chip, and the fourth semiconductor chip are equal to each other in the third direction.

11. The semiconductor package of claim 10, wherein:
an outer wall of the first semiconductor chip and an outer wall of the first spacer are aligned with each other;
an inner wall of the first semiconductor chip and an inner wall of the first spacer are not aligned with each other;
an outer wall of the third semiconductor chip and the outer wall of the second spacer are aligned with each other;
an inner wall of the third semiconductor chip and the inner wall of the second spacer are not aligned with each other; and
a distance in the first direction between the outer wall of the first semiconductor chip and the outer wall of the third semiconductor chip is greater than a distance in the first direction between the inner wall of the first semiconductor chip and the inner wall of the third semiconductor chip.

12. The semiconductor package of claim 10, wherein:
the first spacer is disposed between the first semiconductor chip and the substrate; and
the second spacer is disposed between the third semiconductor chip and the substrate.

13. The semiconductor package of claim 10, wherein:
a distance between the first semiconductor chip and the third semiconductor chip is greater than a distance between the second semiconductor chip and the fourth semiconductor chip.

14. The semiconductor package of claim 10, wherein:
the second semiconductor chip and the fourth semiconductor chip do not overlap each other in the third direction.

15. The semiconductor package of claim 9, further comprising:
a controller disposed between the first spacer and the second spacer and disposed on the substrate.

16. The semiconductor package of claim 15, wherein:
the substrate comprises a wiring structure including a first passivation layer and a second passivation layer spaced apart from each other in the third direction, a first wiring layer in the first passivation layer, and a second wiring layer in the second passivation layer;
the first wiring layer comprises a first upper pad and a second upper pad electrically connected to the first semiconductor chip stack through a first bonding wire, a third upper pad and a fourth upper pad electrically connected to the second semiconductor chip stack through a second bonding wire, and a connecting pad electrically connected to the controller; and
the controller is electrically connected to the substrate through a solder ball connected to the connecting pad.

17. A semiconductor package comprising:
a substrate extending in a first direction and a second direction intersecting the first direction;
a first spacer disposed on the substrate;
a first semiconductor chip stack disposed on the first spacer, the first semiconductor chip includes a plurality of first semiconductor chips stacked in a third direction intersecting the first direction and the second direction;
a second spacer disposed on the substrate, the second spacer is spaced apart from the first spacer in the first direction;
a second semiconductor chip stack disposed on the second spacer, the second semiconductor chip includes a plurality of second semiconductor chips stacked in the third direction;
a mold layer integrally covering the first semiconductor chip stack and the second semiconductor chip stack, the mold layer is in direct contact with side surfaces of the first spacer and side surfaces of the second spacer; and
a controller disposed between the first spacer and the second spacer and disposed on the substrate,
wherein the first spacer comprises a first silicon layer, and a first bonding layer disposed between the first silicon layer and the substrate,
the second spacer includes a second silicon layer, and a second bonding layer disposed between the second silicon layer and the substrate, and
a width of the first spacer in the first direction is greater than a width of the second spacer in the first direction.

18. The semiconductor package of claim 17, wherein:
a height of an upper side of the first bonding layer and a height of an upper side of the second bonding layer are equal to each other with respect to an upper side of the substrate.

19. The semiconductor package of claim 17, wherein:
a height of an upper side of the first bonding layer is greater than a height of an upper side of the second bonding layer with respect to an upper side of the substrate.

20. The semiconductor package of claim 17. wherein:
a height of an upper side of the first bonding layer is less than a height of an upper side of the second bonding layer with respect to an upper side of the substrate.
